(19) United States
(12) Patent Application Publication
(10) Pub. No.: US 2012/0264264 A1
(43) Pub. Date: Oct. 18, 2012

(54) METHOD OF FABRICATING NON-VOLATILE MEMORY DEVICE

(75) Inventors: Chung-Yi Chen, Hsinchu County (TW); Li-Yeat Chen, Miaoli County (TW); Jung-Chun Lin, Hsinchu City (TW)

(73) Assignee: MAXCHIP ELECTRONICS CORP., Hsinchu City (TW)

(21) Appl. No.: 13/537,038

(22) Filed: Jun. 28, 2012

Related U.S. Application Data
(62) Division of application No. 12/635,703, filed on Dec. 11, 2009.

(30) Foreign Application Priority Data
Oct. 21, 2009 (TW) 98135654

(51) Int. Cl. H01L 21/336

(52) U.S. Cl. 438/266; 257/E21.422

(57) ABSTRACT

A method of fabricating a non-volatile memory device is provided. A substrate including a first region and a second region is provided. Then, an uneven surface is formed on the substrate in the second region. Thereafter, a doped layer is formed in the substrate in the second region, and the doped layer is served as a control gate. Afterward, a dielectric layer is formed on the substrate in the first region and on the uneven surface of the substrate in the second region. Next, a floating gate is formed on the dielectric layer, and the floating gate is extended from the first region to the second region. Source and drain regions are formed in the substrate at opposite sides of the floating gate in the first region.

### CROSS-REFERENCE TO RELATED APPLICATION

This application is a Divisional of and claims the priority benefit of U.S. patent application Ser. No. 12/635,703, filed on Dec. 11, 2009, now pending, which claims the priority benefits of Taiwan application Serial No. 98135654, filed on Oct. 21, 2009. The entirety of each of the above-mentioned patent applications is hereby incorporated by reference herein and made a part of this specification.

### BACKGROUND OF THE INVENTION

1. Field of the Invention

The invention relates to a memory and method of fabricating the same, and more particularly, to a non-volatile memory and a method of fabricating the same.

2. Description of Related Art

The non-volatile memory device has the advantages of executing data write, read and erase for many times, and the stored data will not disappear while the power is off. Therefore, the non-volatile memory device is commonly applied in the electronic products.

A typical non-volatile memory device has a stack gate including a floating gate and a control gate located on a substrate. The floating gate is sandwiched between the control gate and the substrate and is disposed in a floating state without electrically connecting to any circuits. The control gate is located above the floating gate and connected to a word line. In addition, a tunneling oxide layer and an inter-gate dielectric layer are further disposed between the substrate and the floating gate and between the floating gate and the control gate, respectively.

The larger the coupled areas between the floating gate and the control gate, the higher the coupling ratio such that the stored capacitance in the non-volatile memory device is increased. However, with the demand of the minimization of the devices, the size of the devices is continuously diminished, and the stored capacitance in the memory device is reduced accordingly. Therefore, a non-volatile memory device and fabricating method thereof capable of decreasing the layout area and improving the coupling efficiency are needed.

### SUMMARY OF THE INVENTION

The invention is directed to a method of fabricating a non-volatile memory device capable of increasing the coupled area between the floating gate and the control gate to improve the coupling efficiency of the memory device by simple and cheap processes.

The invention is directed to a method of fabricating a non-volatile memory device to reduce the layout area and provide sufficient coupled area.

The invention provides a method of fabricating a non-volatile memory device including providing a substrate including a first region and a second region. Then, an uneven surface is formed on the substrate in the second region. Thereafter, a doped layer is formed in the substrate in the second region, and the doped layer is served as a control gate. Afterward, a dielectric layer is formed on the substrate in the first region and on the uneven surface of the substrate in the second region. Next, a floating gate is formed on the dielectric layer, and the floating gate is extended from the first region to the second region. Source and drain regions are formed in the substrate at opposite sides of the floating gate in the first region.

In a method of fabricating a non-volatile memory device according to an embodiment of the invention, the method of forming the uneven surface comprises forming a plurality of trenches in the substrate.

In a method of fabricating a non-volatile memory device according to an embodiment of the invention, the method of forming the trenches includes forming a first isolation structure in the substrate between the first region and the second region, forming a plurality of second isolation structures in the substrate in the second region, and then removing an insulator material in each of the second isolation structures to form the trenches.

In a method of fabricating a non-volatile memory device according to an embodiment of the invention, the method of forming the first isolation structure and the second isolation structures includes a shallow trench isolation (STI) method.

In a method of fabricating a non-volatile memory device according to an embodiment of the invention, the method of forming the first isolation structure and the second isolation structures includes a field oxidation method.

In a method of fabricating a non-volatile memory device according to an embodiment of the invention, a mask layer is further formed on the substrate before removing the insulator material in the second isolation structures, wherein the mask layer has an opening exposing the substrate in the second region and the second isolation structures, and the mask layer is further removed after removing the insulator material in the second isolation structures.

In a method of fabricating a non-volatile memory device according to an embodiment of the invention, the step of forming the doped layer is performed after forming the mask layer and before removing the mask layer.

In a method of fabricating a non-volatile memory device according to an embodiment of the invention, the method of forming the doped layer includes performing an in-situ doped selective area epitaxy growth process by using the mask layer as a mask to form a doped single crystal silicon epitaxial layer on the substrate in the first region.

In a method of fabricating a non-volatile memory device according to an embodiment of the invention, the method of forming the doped layer includes performing an in-situ doped selective epitaxy growth process by using the mask layer as a mask to form a doped hemispherical silicon grains layer on the substrate in the first region.

In a method of fabricating a non-volatile memory device according to an embodiment of the invention, the method of forming the doped layer includes performing an ion implanting process by using the mask layer as a mask to form a doped region in the substrate in the first region.

In a method of fabricating a non-volatile memory device according to an embodiment of the invention, a material of the floating gate includes a doped polysilicon or a polycide layer.

In the invention, the uneven surface is formed to increase the coupled area between the floating gate and the control gate. Thereby, the coupling efficiency of the memory device is improved and the layout area is reduced under the same coupled area. In addition, the trenches are formed simultaneously with the formation of the isolation structures, and no additional mask is needed. Accordingly, the fabricating method of the invention is simple and the cost thereof is cheap.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1E are cross-sectional views schematically depicting a method of fabricating a non-volatile memory device according to one embodiment of the invention.

FIGS. 2A through 2E are cross-sectional views schematically depicting a method of fabricating a non-volatile memory device according to another embodiment of the invention.

### DESCRIPTION OF EMBODIMENTS

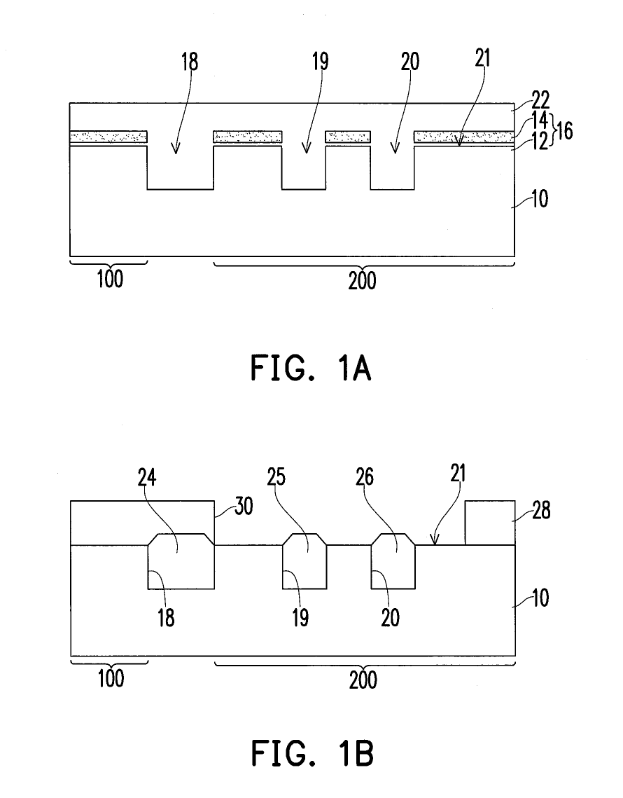

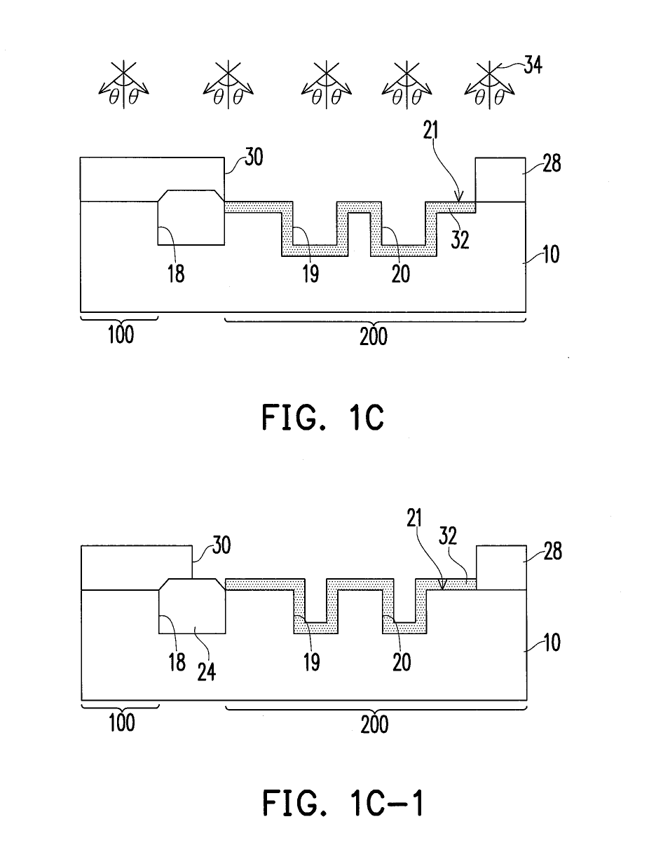

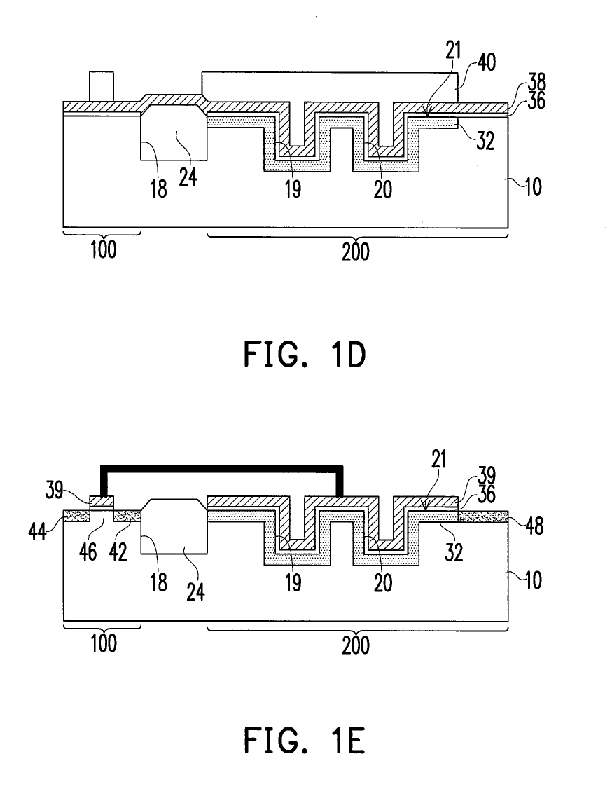

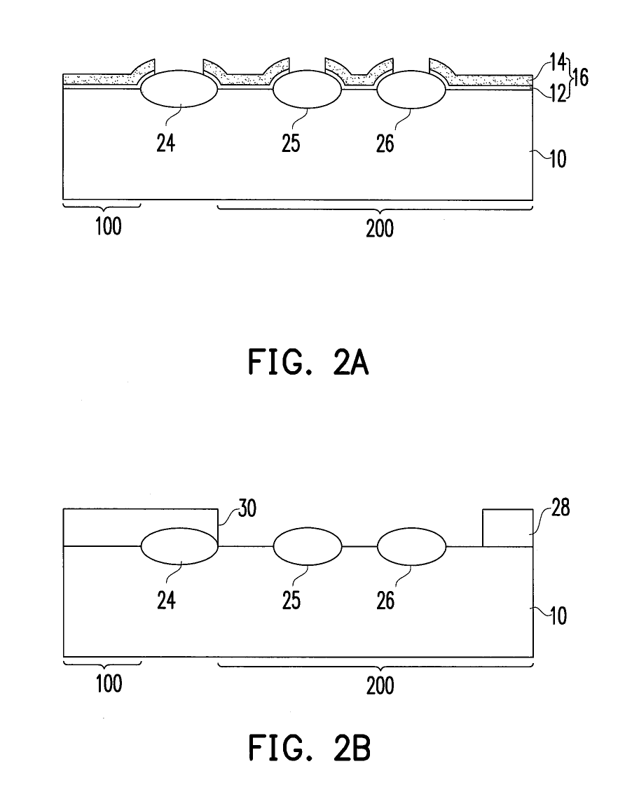

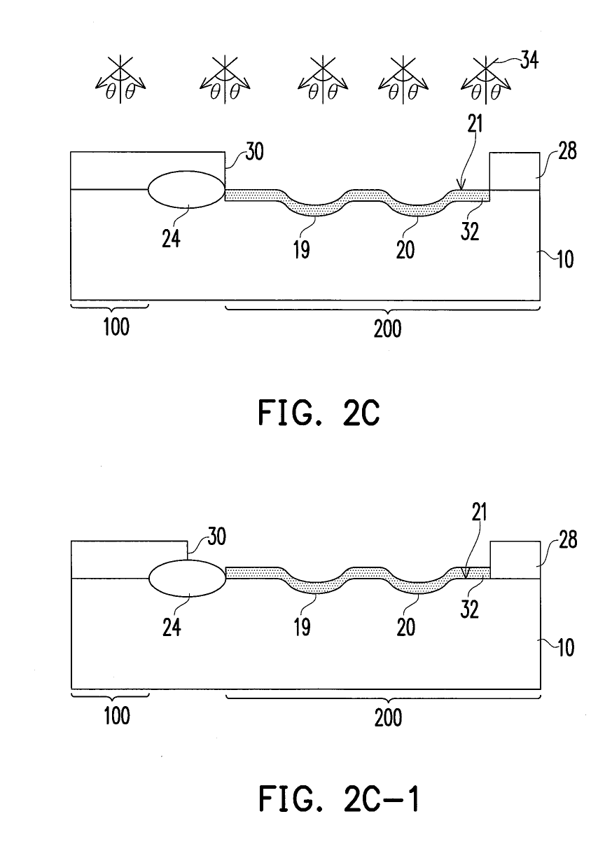

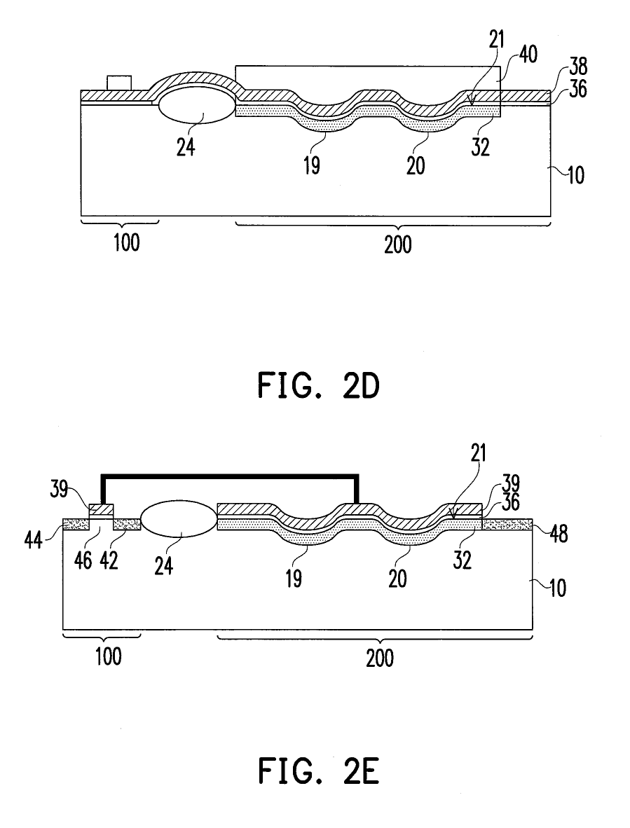

FIG. 1E is a schematic cross-sectional view of a non-volatile memory device according to one embodiment of the present invention. FIG. 2E is a schematic cross-sectional view of a non-volatile memory device according to another embodiment of the present invention.

Referring to FIGS. 1E and 2E, a non-volatile memory device of an embodiment of the invention includes a substrate 10, a dielectric layer 36, a floating gate 39, source and drain regions 42 and 44, a channel region 46, and a doped layer 32. The substrate 10 is, for example, a bulk substrate such as a silicon substrate or a silicon-on-insulator (SOI) substrate. The substrate 10 includes a first region 100 and a second region 200. The first region 100 is separated from the second region 200 by an isolation structure 24. The isolation structure 24 is, for example, a shallow trench isolation structure or a field oxide layer. The substrate 10 has a flat surface in the first region 100, and the substrate 10 has a plurality of trenches 19 and 20 in the second region 200 such that the substrate 10 has an uneven surface 21 in the second region 200. The substrate 10 has the uneven surface 21 in the second region 200, which makes the memory device have larger coupled area between the floating gate and the control gate in the invention. It is adoptable only that the trenches 19 and 20 facilitate the objective of forming the uneven surface. Accordingly, the shapes of the trenches 19 and 20 are not limited to what is shown in the drawings, wherein the bottom of the trenches 19 and 20 can be flat, curved, sharp or multi protrusions, etc, and the sidewalls of the trenches 19 and 20 can be vertical sidewalls, oblique sidewalls, arc sidewalls, etc. The dielectric layer 36 is located on the substrate 10 in the first region 100, and located on the substrate 10 in the second region 200 to cover the uneven surface 21. The dielectric layer 36 is silicon oxide or a stack structure of silicon oxide-silicon nitride-silicon oxide (ONO), for example. The floating gate 39 is located on the dielectric layer 36 in the first region 100 and is continuously extended to the dielectric layer 36 in the second region 200. Namely, the floating gate 39 in the first region 100 and the floating gate 39 in the second region 200 are electrically connected. A material of the floating gate 39 is, for example, a doped polysilicon or a doped polycide layer constituted by a polysilicon layer and a metal silicide layer. The material of the metal silicide layer includes a metal silicide with a refractory metal selected such as nickel, cobalt, titanium, copper, molybdenum, tantalum, tungsten, erbium, zirconium, platinum and an alloy thereof. The source and drain regions 42 and 44 are located in the substrate 10 at opposite sides of the floating gate 39 in the first region 100. In an embodiment, the substrate 10 is a silicon substrate with a p-type dopant or a silicon-on-insulator substrate with a p-type dopant, and the source/drain regions 42 and 44 are n-type doped regions. In another embodiment, the substrate 10 is a silicon substrate with an n-type dopant or a silicon-on-insulator substrate an n-type dopant, and the source/drain regions 42 and 44 are p-type doped regions. The dopant in the p-type doped region is, for example, boron. The dopant in the n-type doped region is, for example, phosphorus or arsenic. The channel region 46 is located in the substrate 10 between the source and drain regions 42 and 44. The doped layer 32 is located on the uneven surface 21 or in the substrate 10 in the second region 200 to be served as a control gate coupled with the floating gate 39. The dopant in the doped layer 32 may be n-type or p-type. The order of magnitude of the dopant concentration in the doped layer 32 is, for example, 10¹⁹ per cm³ to 10²² per cm³. The doped layer 32 can be a doped region or a doped selective epitaxial layer. The doped region is formed inside the substrate 10 having the uneven surface 21 by an ion implanting process as shown in FIG. 1C. The doped selective epitaxial layer can be a single crystal silicon epitaxial layer or a doped hemispherical silicon grains layer, and is formed on the substrate 10 having the uneven surface 21 by a selective area epitaxy growth process as shown in FIG. 1C-1.

FIGS. 1A through 1E are cross-sectional views schematically depicting a method of fabricating a non-volatile memory device according to one embodiment of the invention.

Referring to FIG. 1A, the substrate 10 includes the first region 100 and the second region 200. The substrate 10 is, for example, a bulk substrate such as a silicon substrate or an SOI substrate. An isolation structure is predetermined formed between the first region 100 and the second region 200. A mask layer 16 is formed on the substrate 10. The mask layer 16 is consisted of a pad oxide layer 12 and a silicon nitride layer 14, for example. Then, the mask layer 16 is patterned and a trench 18 is formed inside the substrate 10 between the first region 100 and the second region 200. Simultaneously, trenches 19 and 20 are formed in the substrate 10 in the second region 200. In one embodiment, the depths of the trenches 19 and 20 are about 2,500 angstroms to 3,000 angstroms. Thereafter, an insulator layer 22 is formed on the mask layer 16 and filled in the trenches 18, 19, and 20. A material of the insulator layer 22 is, for example, silicon oxide formed by a plasma-enhanced chemical vapor deposition process (PECVD), an atmospheric-pressure chemical vapor deposition process (APCVD), a high density plasma chemical vapor deposition (HDPCVD) process and so forth.

Then, referring to FIG. 1B, the insulator layer 22 on the mask layer 16 is removed and the insulator layer 22 filled in the trenches 18, 19, and 20 are remained to form the shallow trench isolation structures 24, 25, and 26. The method for removing the insulator layer 22 is, for example, a chemical mechanical polishing process (CMP), or an etching back process. The mask layer 16 is then removed. The method of removing the mask layer 16 includes, for example, performing a wet etching process or a dry etching process. Thereafter, another mask layer 28 is subsequently formed on the substrate 10. The mask layer 28 can be a photoresist layer, for example. The mask layer 28 has an opening 30 exposing the shallow trench isolation structures 25 and 26 in the second region 200.

Referring to FIGS. 1C and 1C-1, the insulator layer served as shallow trench isolation structures 25 and 26 is removed to expose the trenches 19 and 20 so that the trenches 19 and 20 and the substrate 10 together form the uneven surface 21. The method for removing the insulator layer served as the shallow trench isolation structures 25 and 26 can be the etching process such as the wet etching process or the dry etching process. Thereafter, a doped layer 32 is formed in the substrate 10 in the second region 200 to reduce the impedance, and the doped layer 32 is served as a control gate. The doped layer 32 is a doped region, a doped single crystal silicon epitaxial layer or a doped hemispherical silicon grains layer, for example. The dopant in the doped layer 32 may be n-type or p-type. The n-type dopant is, for example, phosphorous or arsenic. The p-type dopant, for example, is boron.

In one embodiment, referring to FIG. 1C, the doped layer 32 is a doped region formed by performing an ion implanting process 34 on the substrate 10 having the uneven surface 21 in the second region 200 by using the mask layer 28 as a mask. The ion implanting process 34 can be a tilt ion implanting process which has an implanting direction inclining from the normal of the substrate 10 by an incline angle θ from 15 degree to 60 degree.

In another embodiment, referring to FIG. 1C-1, the doped layer 32 is a doped single crystal silicon epitaxial layer or a doped hemispherical silicon grains layer formed by performing a selective area epitaxy growth process on the substrate 10 having the uneven surface 21 in the second region 200 by using the mask layer 28 as a mask. The dopant of the single crystal silicon epitaxial layer or the hemispherical silicon grains layer can be in-situ doped during performing the selective area epitaxy growth process or formed by performing an ion implanting process after performing the selective area epitaxy growth process.

Afterwards, referring to FIG. 1D, the mask layer 28 is removed. A dielectric layer 36 is then formed on the substrate 10 in the first region 100 and on the uneven surface 21 of the substrate 10 in the second region 200. The material of the dielectric layer 36 is, for example, silicon oxide, and the method for fabricating the same is, for instance, a thermal oxidation process or a chemical vapor deposition process. Certainly, the material of the dielectric layer 32 can also be a stack layer of silicon oxide-silicon nitride-silicon oxide (ONO). Next, a conductive layer 38 is formed on the dielectric layer 36 in the first region 100 and the second region 200. The material of the conductive layer 38 is, for example, a doped polysilicon or a metal polycide layer constituted by doped polysilicon and a silicide compound formed by the chemical vapor deposition process. After that, another mask layer 40 is formed on the conductive layer 38. The mask layer 40 covers an area where a floating gate is predetermined formed. The material of the mask layer 40 is, for example, a photo resist material.

Referring to FIG. 1E, the conductive layer 38 is patterned to form the floating gate 39. The method of patterning the conductive layer 38 is performing an etching process by using the mask layer 40 as a mask to remove the conductive layer 38 not covered by the mask layer 40 and the underlying dielectric layer 36 such that the remained conductive layer 38 is served as the floating gate 39, wherein the underlying dielectric layer 36 is the dielectric layer 36 right under the conductive layer 38 not covered by the mask layer 40. The floating gate 39 is located on the dielectric layer 36 in the first region 100 and is continuously extended to the dielectric layer 36 in the second region 200. Thereafter, the mask layer 40 is removed. The source and drain regions 42 and 44 are formed in the substrate 10 at opposite sides of the floating gate 39 in the first region 100. The channel region 46 is located between the source and drain regions 42 and 44. Afterwards, a doped region 48 is formed in the substrate 10 in the second region 200. The conductive type of the doped region 48 is the same as that of the doped region 32 and the doped region 48, serving as a pick up region to be connected to a word line, is electrically connected to the doped region 32.

In the abovementioned embodiment, the isolation structures 24, 25, and 26 are formed by typical shallow trench isolation process. Nevertheless, the invention is not limited thereto, and the isolation structures 24, 25, and 26 can be formed by the field oxidation process. The detailed description is given as follows.

FIGS. 2A through 2E are cross-sectional views schematically depicting a method of fabricating a non-volatile memory device according to one embodiment of the invention.

Referring to FIG. 2A, the mask layer 16 is formed by the aforesaid process on the substrate 10 and is patterned. Next, a field oxidation process is performed by oxidizing the substrate 10 exposed by the mask layer 16 to form the field oxide layer, e.g. an insulator layer, served as the isolation structures 24, 25, and 26. In one embodiment, the depth of the field oxide layer is about 4,000 angstroms to 5,000 angstroms.

Afterwards, referring to. FIG. 2B, the mask layer 16 is removed. Referring to FIG. 2C, another mask layer 28 is formed on the substrate 10, and the field oxide layer (or the insulator layer) in the isolation structures 25 and 26 is removed to form the trenches (or concaves) 19 and 20. Owing that the isolation structures 24, 25, and 26 are formed by the field oxidation process, the trenches 19 and 20 formed by removing the field oxide layer (or the insulator layer) in the isolation structures 25 and 26 have arc bottoms. Though the shapes of the trenches 19 and 20 in the present embodiment are different from those in the previous embodiment, the trenches 19 and 20 are provided to form the uneven surface. The following processes are similar to the aforementioned embodiment. Detailed descriptions thereof are thus omitted.

The uneven surface is formed in the invention to increase the coupled area between the floating gate and the control gate. Thereby, the coupling efficiency of the memory device is improved and the layout area is reduced. In addition, the trenches are formed simultaneously with the formation of the isolation structures, and no additional mask is needed. Accordingly, the fabricating method of the invention is simple and the cost thereof is cheap.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A method of fabricating a non-volatile memory device, comprising:
providing a substrate including a first region and a second region;
forming an uneven surface on the substrate in the second region;
forming a doped layer in the substrate in the second region, and the doped layer being served as a control gate;
forming a dielectric layer located on the substrate in the first region and on the uneven surface of the substrate in the second region;
forming a floating gate on the dielectric layer, and the floating gate being extended from the first region to the second region; and
forming source and drain regions in the substrate at opposite sides of the floating gate in the first region.

2. The method of fabricating the non-volatile memory device of claim 1, wherein the method of forming the uneven surface comprises forming a plurality of trenches in the substrate.

3. The method of fabricating the non-volatile memory device of claim 2, wherein a method of forming the trenches comprises:
forming a first isolation structure between the first region and the second region of the substrate, and forming a plurality of second isolation structures in the second region of the substrate; and
removing an insulator material in the second isolation structures to form the trenches.

4. The method of fabricating the non-volatile memory device of claim 3, wherein the method of forming the first isolation structure and the second isolation structures comprises a shallow trench isolation (STI) method.

5. The method of fabricating the non-volatile memory device of claim 3, wherein the method of forming the first isolation structure and the second isolation structures comprises a field oxidation method.

6. The method of fabricating the non-volatile memory device of claim 3, wherein
before removing the insulator material in the second isolation structures, a mask layer is further formed on the substrate, and the mask layer has an opening exposing the substrate in the second region and the second isolation structures; and
after removing the insulator material in the second isolations, the mask layer is further removed.

7. The method of fabricating the non-volatile memory device of claim 6, wherein the step of forming the doped layer is performed after forming the mask layer and before removing the mask layer.

8. The method of fabricating the non-volatile memory device of claim 7, wherein the method of forming the doped layer comprises performing an in-situ doped selective area epitaxy growth process by using the mask layer as a mask to form a doped single crystal silicon epitaxial layer on the first region of the substrate.

9. The method of fabricating the non-volatile memory device of claim 7, wherein the method of forming the doped layer comprises performing an in-situ doped selective epitaxy growth process by using the mask layer as a mask to form a doped hemispherical silicon grains layer on the first region of the substrate.

10. The method of fabricating the non-volatile memory device of claim 7, wherein the method of forming the doped layer comprises performing an ion implanting process by using the mask layer as a mask to form a doped region in the substrate in the first region.
